(19) United States
(12) Patent Application Publication
(10) Pub. No.: US 2026/0181333 A1
(43) Pub. Date: Jun. 25, 2026

(54) SOUND-GENERATING DEVICE AND MANUFACTURING METHOD THEREFOR, AND DISPLAY APPARATUS

(71) Applicants: HEFEI BOE OPTOELECTRONICS TECHNOLOGY CO., LTD., Hefei, Anhui (CN); BOE Technology Group Co., Ltd., Beijing (CN)

(72) Inventors: Juncai Ma, Beijing (CN); Yingxi Tai, Beijing (CN); Wenjuan Mei, Beijing (CN); Xiaobin Yin, Beijing (CN); Jie Yang, Beijing (CN); Zhengwei Zhu, Beijing (CN)

(73) Assignees: HEFEI BOE OPTOELECTRONICS TECHNOLOGY CO., LTD., Hefei, Anhui (CN); BOE Technology Group Co., Ltd., Beijing (CN)

(21) Appl. No.: 18/840,562

(22) PCT Filed: Sep. 19, 2023
(86) PCT No.: PCT/CN2023/119752

§ 371 Date: Aug. 22, 2024

(51) Int. Cl. H04R 19/02; G02F 1/1333; H04R 1/02; H04R 1/40; H04R 31/00

(52) U.S. Cl. CPC H04R 19/02; G02F 1/1333; H04R 1/025; H04R 1/403; H04R 31/003; H04R 2231/003; H04R 2499/15

(57) ABSTRACT

A sound-generating device and manufacturing method therefor, and a display apparatus are provided by the present application, the sound-generating device includes a first substrate, a first conducting layer, a first protecting layer, an organic layer, a plurality of supporting portion sets arranged in an array and a sound-generating vibration layer. The first conducting layer is located at one side of the first substrate. The first protecting layer covers the first conducting layer. The organic layer is located at one side of the first protecting layer away from the first conducting layer. Each of the plurality of supporting portion sets includes at least one supporting portion, each of the at least one supporting portion is located at one side of the organic layer away from the first protecting layer.

### TECHNICAL FIELD

The present disclosure relates to the technical field of acoustics and, more particularly, to a sound-generating device and manufacturing method therefor, and a display apparatus.

### BACKGROUND

With the increase of audio-visual scenes, directional sound technology emerges as the times require. In the directional sound technology, by modulating audio signals and ultrasonic carrier signals, the energy of emitted sound waves is concentrated, audible sound waves with strong directivity are formed, the law of sound propagating in all directions is broken and an independent audio space that does not interfere with the surrounding environment is created.

### SUMMARY

The following technical solutions are adopted by the embodiments of the present application.

In a first aspect, a sound-generating device is provided by the embodiments of the present application, including:
a first substrate;
a first conducting layer located at one side of the first substrate;
a first protecting layer covering the first conducting layer;
an organic layer located at one side of the first protecting layer away from the first conducting layer;
a plurality of supporting portion sets arranged in an array, each of the plurality of supporting portion sets including at least one supporting portion, each of the at least one supporting portion being located at one side of the organic layer away from the first protecting layer;
a sound-generating vibration layer located atone side of each supporting portion set away from the first substrate, the plurality of supporting portion sets being located in a cavity structure formed by the first protecting layer and the sound-generating vibration layer;
wherein an area of an orthographic projection of the organic layer on the first substrate is greater than a sum of areas of orthographic projections of all supporting portions on the first substrate, and at least part of areas of each of the at least one supporting portion is directly contacted with the organic layer.

In the at least one embodiment of the present application, the sound-generating device includes a light-transmitting area and a non-light-transmitting area surrounding the light-transmitting area, the orthographic projection of the organic layer on the first substrate covers a part of the first substrate located in the light-transmitting area, each of the at least one supporting portion is disposed on the organic layer, and each of the at least one supporting portion and the organic layer are made of a same type of material.

In the at least one embodiment of the present application, the organic layer includes a plurality of raised height portions arranged in an array, and there is a slot between two adjacent raised height portions, and a quantity of the plurality of raised height portions is the same as a quantity of the plurality of supporting portion sets;
wherein an orthographic projection of each supporting portion set on the first substrate is located within an orthographic projection of a corresponding raised height portion on the first substrate, and the at least part of areas of each of the at least one supporting portion in the supporting portion set is directly contacted with the corresponding raised height portion.

In the at least one embodiment of the present application, sizes of graphs of the orthographic projections of the plurality of raised height portions on the first substrate are the same; an area of the orthographic projection of the raised height portion on the first substrate is greater than at least 50% of an area of an orthographic projection of a corresponding supporting portion set on the first substrate.

In the at least one embodiment of the present application, each of the at least one supporting portion includes a first surface, and at least part of areas of the first surface is directly contacted with the corresponding raised height portion, and an area of a contacting surface between the supporting portion and the corresponding raised height portion is greater than at least 50% of an area of the first surface.

In the at least one embodiment of the present application, each supporting portion set includes at least two supporting portions, orthographic projections of the at least two supporting portions in a same supporting portion set on the first substrate are located within the orthographic projection of the corresponding raised height portion on the first substrate, there is a gap between two adjacent supporting portions in the same supporting portion set, or the two adjacent supporting portions in the same supporting portion set are connected.

In the at least one embodiment of the present application, the sound-generating device further includes an inorganic layer, the inorganic layer is located at one side of the organic layer away from the first substrate, the inorganic layer at least covers side surfaces of the plurality of raised height portions and extends to cover a bottom of the slot, and a part of the inorganic layer located at the bottom of the slot is directly contacted with the first protecting layer.

In the at least one embodiment of the present application, there area plurality of openings on the inorganic layer, and an area enclosed by an orthographic projection of an outer contour of each opening on the first substrate is located within the orthographic projection of the corresponding raised height portion on the first substrate, and the at least part of areas of each of the at least one supporting portion is located within the opening.

In the at least one embodiment of the present application, a size of an area enclosed by an outer contour of a same supporting portion set is less than or equal to a size of an area enclosed by an outer contour of a corresponding opening, and the corresponding supporting portion is disposed within the corresponding opening and is directly contacted with the corresponding raised height portion.

In the at least one embodiment of the present application, a size of an area enclosed by an outer contour of a same supporting portion set is greater than a size of an area enclosed by an outer contour of a corresponding opening, a pan of areas of the corresponding supporting portion is disposed within the corresponding opening, and the corresponding supporting portion further covers a part of the inorganic layer.

In the at least one embodiment of the present application, a material of each of the at least one supporting portion is the same as a material of the organic layer.

In the at least one embodiment of the present application, a material of the inorganic layer is the same as a material of the first protecting layer.

In the at least one embodiment of the present application, a geometric center of a graph of the orthographic projection of each supporting portion set on the first substrate approximately overlaps with a geometric center of a graph of the orthographic projection of the corresponding raised height portion on the first substrate.

In the at least one embodiment of the present application, when the supporting portion set includes a supporting portion, in any direction parallel to a plane where the first substrate is located, distances from edges of a graph of an orthographic projection of the supporting portion on the first substrate to edges of a graph of the orthographic projection of the corresponding raised height portion on the first substrate are approximately equal.

In the at least one embodiment of the present application, in any direction parallel to a plane where the first substrate is located, a size of the slot is greater than a size of each of the two adjacent raised height portions.

In the at least one embodiment of the present application, a distance between any two adjacent raised height portions ranges from 0.5 mm to 5 mm.

In the at least one embodiment of the present application, heights of the at least one supporting portion in a same supporting portion set in a direction perpendicular to the first substrate am equal.

In the at least one embodiment of the present application, each supporting portion set includes a first supporting portion and a second supporting portion, heights of the first supporting portions in a direction perpendicular to the first substrate are equal, heights of the second supporting portions in the direction perpendicular to the first substrate are equal, and the height of the first supporting portion in the direction perpendicular to the first substrate is greater than die height of the second supporting portion in the direction perpendicular to the first substrate.

In the at least one embodiment of the present application, the sound-generating vibration layer includes a second substrate and a second conducting layer located between the second substrate and the plurality of supporting portion sets, and the cavity structure is formed between the first protecting layer and the second conducting layer; and
a height of each of the at least one supporting portion in a direction perpendicular to the plane where the first substrate is located is less than a minimum distance from a surface of the supporting portion adjacent to the first substrate to the second conducting layer.

In the at least one embodiment of the present application, the sound-generating device includes a light-transmitting area and a non-light-transmitting area surrounding the light-transmitting area, and the plurality of supporting portion sets are disposed in the light-transmitting area;
the non-light-transmitting area includes a first perimeter wiring, a second perimeter wiring, a second protecting layer and a bonding portion, the first perimeter wiring is located between the first conducting layer and the first protecting layer; the first perimeter wiring and the first conducting layer are electrically connected; the second perimeter wiring is disposed at one side of the second conducting layer close to the first substrate, and the second protecting layer covers a side of the second perimeter wiring away from the second conducting layer; the second perimeter wiring and the second conducting layer are electrically connected; at least part of areas of the bonding portion is disposed between the inorganic layer and the second protecting layer; and
in the direction perpendicular to the plane where the first substrate is located, a height of the bonding portion is greater than a sum of a height of each of the at least one supporting portion and a height of the corresponding raised height portion.

In the at least one embodiment of the present application, in a first direction or a second direction, distances between any two adjacent raised height portions are approximately equal; and
in the first direction or the second direction, for the raised height portion with a minimum distance to a junction position of the non-light-transmitting area and the light-transmitting area, the distance from the raised height portion to the junction position is approximately equal to the distances between any other two adjacent raised height portions, and the first direction and die second direction are perpendicular.

In the at least one embodiment of the present application, the sum of the height of each of the at least one supporting portion and the height of the corresponding raised height portion ranges from 4 μm to 15 μm.

In the at least one embodiment of the present application, a ratio of the height of each of to the at least one supporting portion to the height of the corresponding raised height portion is approximately 5:3.

In the at least one embodiment of the present application, a shape of a graph of an orthographic projection of each of the at least one supporting portion on the first substrate and a shape of a graph of the orthographic projection of the corresponding raised height portion on the first substrate are shapes.

In a second aspect, a display apparatus is provided by the embodiments of the present application, wherein the display apparatus includes the sound-generating device according to any one of embodiments in the first aspect, and further includes a display panel, the sound-generating device is disposed at a light exiting side of the display panel or inside the display panel, and an orthographic projection of a light-transmitting area of the sound-generating device on the display panel overlaps with a displaying region of the display panel.

In the at least one embodiment of the present application, the display panel includes a liquid crystal display panel, the sound-generating device is disposed at the light exiting side of the display panel; and
the orthographic projections of at least part of the at least one supporting portions on the liquid crystal display panel overlap with spacers in the liquid crystal display panel.

In the at least one embodiment of the present application, the display panel includes an organic light-emitting diode display panel, and the sound-generating device is disposed at the light-emitting side of the display panel or inside the display panel.

In a third aspect, a method for manufacturing the sound-generating device is provided by the embodiments of the present application, applied to the sound-generating device according to any one of embodiments in the first aspect, the method includes:
providing the first substrate;
forming the first conducting layer, the first protecting layer and the organic layer on the first substrate, respectively; and
forming the plurality of supporting portion sets arranged in the array; wherein each of the plurality of supporting portion sets includes at least one supporting portion, each of the at least one supporting portion is located at the side of the organic layer away from the first protecting layer; the area of the orthographic projection of the organic layer on the first substrate is greater than the sum of the areas of the orthographic projections of all supporting portions on the first substrate, and at least part of areas of each of the at least one supporting portion is directly contacted with the organic layer.

In the at least one embodiment of the present application, the organic layer includes a plurality of raised height portions arranged in an array, and there is a slot between the two adjacent raised height portions, and a quantity of the plurality of raised height portions is the same as a quantity of the plurality of supporting portion sets; after the forming the organic layer, and before the forming the plurality of supporting portion sets arranged in the array, the method further includes:
forming an inorganic layer on the organic layer, wherein there are a plurality of openings on the inorganic layer, and an area enclosed by an orthographic projection of an outer contour of each opening on the first substrate is located within an orthographic projection of a corresponding raised height portion on the first substrate, and the at least part of areas of each of the at least one supporting portion is directly contacted with the corresponding raised height portion through a corresponding opening.

In the at least one embodiment of the present application, after forming the inorganic layer on the organic layer, and after forming the plurality of supporting portion sets, the method further includes:
providing a second substrate;
forming a second conducting layer on the second substrate; and
disposing a bonding layer in apart of the inorganic layer located in non-light-transmitting area of the sound-generating device, wherein the inorganic layer and the second protecting layer are bonded together by using the bonding layer.

The above description is merely a summary of the technical solutions of the present application. In order to more clearly know the elements of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the figures that are required to describe the embodiments or the prior an may be briefly described below. Obviously, the figures that are described below are some embodiments of the present application, and a person skilled in the art can obtain other figures according to these figures without paying creative work.

FIG. 1 is a schematic diagram of a partial structure of a sound-generating device in the related art;

FIG. 2 is a scanning electron microscope image of the sound-generating device shown in FIG. 1 before the supporting column fills off;

FIG. 3 is a scanning electron microscope image of the sound-generating device shown in FIG. 1 after the supporting column fills off;

FIGS. 4 to 12 are schematic diagrams of cross-sectional structures of nine sound-generating devices according to embodiments of the present application;

FIGS. 13 and 16 are top view schematic structural diagrams of partial structures of two sound-generating devices according to embodiments of the present application;

FIG. 14 is a schematic diagram of a cross-sectional structure in FIG. 16 along an M1M2 direction;

FIG. 15 is a schematic diagram of a cross-sectional structure in FIG. 13 along an M3M4 direction;

FIGS. 17 to 19 are schematic diagrams of cross-sectional structures of three display apparatuses according to embodiments of the present application;

FIGS. 20 to 22 are schematic diagrams of three intermediate structures of a sound-generating device during the manufacturing process according to embodiments of the present application;

FIGS. 23 to 25 are schematic diagrams of intermediate structures of a display apparatus during the manufacturing process according to embodiments of the present application; and

FIG. 26 is a schematic diagram of a cross-sectional structure of another sound-generating device according to embodiments of the present application.

### DETAILED DESCRIPTION

The technical solutions in the embodiments of the present application may be clearly and completely described below with reference to the drawings of the embodiments of the present application. Apparently, the described embodiments are merely certain embodiments of the present application, rather than all of the embodiments. All of the other embodiments that a person skilled in the art obtains on the basis of the embodiments of the present application without paying creative work fall within the protection scope of the present application.

In die embodiments of the present application, terms such as “first”, “second”, “third” and “fourth” are used to distinguish identical items or similar items that have substantially the same functions and effects, merely in order to clearly describe the technical solutions of the embodiments of the present application, and should not be construed as indicating or implying the degrees of importance or implicitly indicating the quantity of the specified technical features.

In the embodiments of the present application, an orientation or positional relationship indicated by the terms “upper” and “lower” are based on orientation or positional relationships shown in the drawings, and are merely for convenience of describing the present application and simplifying the description, rather than indicate or imply that the device or element referred to must have a specific orientation, be configured and operated in a specific orientation, and thus cannot be understood as a limitation on the present application.

In the description of the specification, the terms “one embodiment” “some embodiments”, “exemplary embodiments”, “example”, “specific example” or “some examples” are intended to indicate that specific features, structures, materials or characteristics related to the embodiment or example are included in at least one embodiment or example of the present application. The illustrative indication of the above terms does not necessarily refer to the same one embodiment or example. Moreover, the specific features, structures, materials or characteristics may be included in any one or more embodiments or examples in any suitable manner.

In the embodiments of the present application, the meaning of“a plurality of” is two or more, and the meaning of “at least one” is one or more, unless otherwise specifically defined.

In the embodiments of the present application, the terms “parallel”, “vertical”, “same” and the like include strict interpretations of “parallel”, “vertical”, “same”, as well as situations where they are “approximately parallel”, “approximately vertical”, “approximately the same”, with certain tolerances considered, taking into account measurements and tolerances related to measurements of specific quantities (for example, limitations of measurement systems), representing acceptable deviation ranges determined by a person skilled in the art for specific values. For example, “approximately” can indicate that the value is within one or more standard deviations, or the value is within 10% or 5% of the value.

Unless otherwise specified in the context, the term “including” is interpreted as meaning open-ended or inclusive throughout the entire specification and claims, i.e., “including, but not limited to”.

In the embodiments of the present application, “same layer” refers to the relationship between multiple film layers formed from the same material after undergoing the same step (for example, a single-step patterning process). Here, “same layer” does not always mean that the thicknesses of multiple film layers are the same or that the heights of multiple film layers are the same in a cross-sectional view. The polygons mentioned in the specification are not strictly defined and can be approximate triangles, parallelograms, trapezoids, pentagons, or hexagons, etc., with some minor deformations due to tolerances.

With the increase of audio-visual scenes, directional sound technology emerges as the times require. In the directional sound technology, by modulating audio signals and ultrasonic carrier signals and using the directivity characteristics of ultrasonic waves, the energy of emitted sound waves is concentrated, audible sound waves with strong directivity are formed, the law of sound propagating in all directions is broken and an independent audio space that does not interfere with the surrounding environment is created.

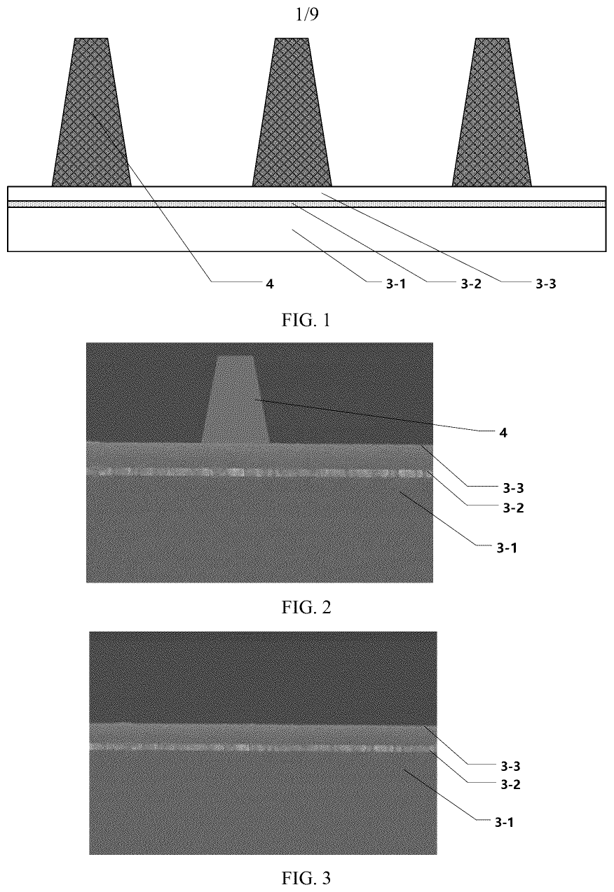

In the related art, in the directional sound-generating device, it is generally provided with a first electrode, a second electrode and a supporting column 4 located between the first electrode and the second electrode. A cavity is formed between the first electrode and the second electrode, and the supporting column is disposed on the first electrode. The second electrode can vibrate, and the supporting column is configured to control the acoustic direction of the sound-generating device. However, as shown in FIG. 1, the sound-generating device includes the first electrode 3-2 and the electrode protecting layer 3-3, which are sequentially disposed on the substrate 3-1, and the supporting column 4 is disposed on the electrode protecting layer 3-3. In combination with the scanning electron microscope (SEM) images shown in FIG. 2 and FIG. 3, in the process of vibration of the directional sound-generating device, the supporting column 4 is easy to fall oft FIG. 2 is the SEM image before the supporting column 4 falls off, and FIG. 3 is the SEM image after the supporting column 4 falls off. In this way, on the one hand, after the supporting column 4 falls of, it falls into other areas of the sound-generating device, causing de uneven transmittance of the sound-generating device, which may resalt in a decrease in the aesthetic of the appearance. On the other hand, the falling off of the supporting column 4 changes the direction of the directional sound-generating, a phenomenon of sound leakage very easily occurs, and an effect of the directional sound-generating is reduced. When the sound-generating device is applied to the display apparatus, the falling off of the supporting column 4 is highly likely to cause that a problem of uneven brightness occurs in the displaying region of the display apparatus to reduce the displaying effect.

Based on this, a sound-generating device and manufacturing method therefor, and a display apparatus are provided by the embodiments of the present application. The sound-generating device includes a first substrate, a first conducting layer, a first protecting layer, an organic layer, a plurality of supporting portion sets arranged in an array and a sound-generating vibration layer. The first conducting layer is located at one side of the first substrate. The first protecting layer covers the first conducting layer. The organic layer is located at one side of the first protecting layer away from the first conducting layer. Each of the plurality of supporting portion sets includes at least one supporting portion, each of the at least one supporting portion is located at one side of the organic layer away from the first protecting layer. The sound-generating vibration layer is located at one side of each supporting portion set away from the first substrate, the plurality of supporting portion sets are located in a cavity structure formed by the first protecting layer and the sound-generating vibration layer. An area of an orthographic projection of the organic layer on the first substrate is greater than a sum of areas of orthographic projections of all supporting portions on the first substrate, and at least part of areas of each supporting portion is directly contacted with the organic layer.

In the embodiment of the present application, by that the organic layer is disposed between the rust protecting layer and the plurality of supporting portion sets, and the area of the orthographic projection of the organic layer on the first substrate is greater than the sum of areas of orthographic projections of all supporting portions on the first substrate, and at least part of areas of each supporting portion is directly contacted with the organic layer, in this way, by using the organic layer, the force between the supporting portion sets and the first protecting layer can be increased, and the organic layer can play a role in buffering the energy generated by the vibration. In the process of the vibration of the sound-generating device, the risk of falling off of the supporting portion is greatly reduced. Thus, the quality of the sound-generating device is improved, and the effect of the directional sound-generating of the sound-generating device is ensured.

In combination with the drawings, a sound-generating device and manufacturing method therefor, and a display apparatus provided by tire embodiments of the present application will be introduced and illustrated in detail in the following.

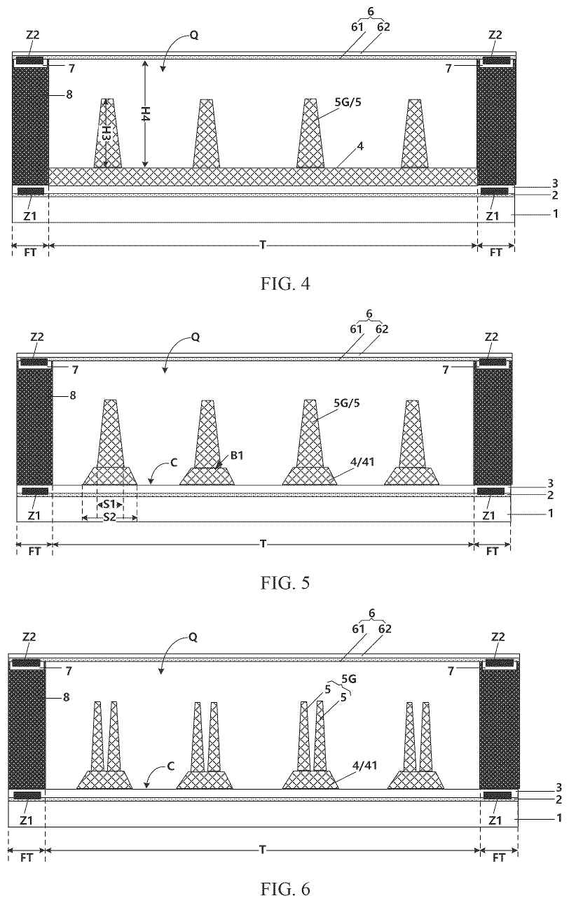

A sound-generating device is provided by the embodiments of the present application, as shown in FIG. 4 to FIG. 12, the sound-generating device includes:
a first substrate 1;
a first conducting layer 2 located at one side of the first substrate 1;
a first protecting layer 3 covering the first conducting layer 2;
an organic layer 4 located at one side of the first protecting layer 3 away from the first conducting layer 2;
a plurality of supporting portion sets 5G arranged in an array, each of the plurality of supporting portion sets 5G including at least one supporting portion 5, each of the at least one supporting portion 5 being located at one side of the organic layer 4 away from the first protecting layer 3;
a sound-generating vibration layer 6 located at one side of each supporting portion set 5G away from the first substrate 1, the plurality of supporting portion sets 5G being located in a cavity structure Q formed by the first protecting layer 3 and the sound-generating vibration layer 6;
wherein an area of an orthographic projection of the organic layer 4 on the first substrate 1 is greater than a sum of areas of orthographic projections of all supporting portions 5 on the first substrate 1, and at least part of areas of each supporting portion 5 is directly contacted with the organic layer 4.

A material of the first substrate 1 is not limited here.

In some examples, the material of the first substrate 1 can be made from one or more of the materials of glass, polyimide, polycarbonate, polyacrylate, polyetherimide, and polyethersulfone, the present embodiment includes, but is not limited to this.

In some examples, the first substrate may be a rigid substrate or a flexible substrate.

When the first substrate 1 is a flexible substrate, the first substrate 1 may include a single layer of a flexible material layer; or, the first substrate 1 may include a first flexible material layer, a first inorganic non-metallic material layer, a second flexible material layer and a second inorganic non-metallic material layer that are arranged in layer configuration. The material of the first flexible material layer and the material of the second flexible material layer are selected from materials such as polyimide (PI), polyethylene terephthalate (PET) or surface-treated polymer soft film. The material of the first inorganic non-metallic material layer and the material of the second inorganic non-metallic material layer are selected from silicon nitride (SiNx) or silicon oxide (SiOx), which is used to improve the water and oxygen resistance of the first substrate 1. The first inorganic non-metallic material layer and the second inorganic non-metallic material layer are also called the barrier layer. In this way, the reliability of the sound-generating device can be improved and the service life of the sound-generating device can be increased.

When the first substrate 1 is a rigid substrate, the first substrate 1 may include a glass substrate.

It should be noted that, when the sound-generating device is applied to the display apparatus, the first substrate can be preferred as a flexible substrate to reduce the thickness of the sound-generating device, thereby the volume of the display apparatus is reduced, the display apparatus is caused to be lighter and thinner, and the application scenario of the sound-generating device is expanded.

A material of the first conducting layer 2 is not limited here.

In some examples, the material of the first conducting layer 2 is a transparent conductive material.

Exemplarily, the material of the first conducting layer 2 is metal. At this moment, in order to achieve light transmittance, the metal film layer has a small thickness. For example, a thickness of the metal film layer is on the nanometer scale.

Exemplarily, the material of the first conducting layer 2 is a metal oxide, such as indium tin oxide (ITO) or indium zinc oxide (IZO).

It should be noted that the sound-generating device may be a directional sound-generating device and applied to the display panel to form a display apparatus with a directional sound-generating function. The sound-generating device is usually disposed at the light exiting side of the display panel, so most of the area of the sound-generating device is required to have a good light transmittance performance.

In the exemplary embodiment, the material of the first protecting layer 3 and the material of the supporting portion 5 are different, for example, the material of the first protecting layer 3 is inorganic material, and the material of the supporting portion 5 is organic material.

In the exemplary embodiment, the material of the supporting portion 5 is a transparent material.

In the exemplary embodiment, the material of the first protecting layer 3 is an insulating material, which is used to isolate the first conducting layer 2 from other conductive materials to avoid short circuit in the circuit. In addition, the first protecting layer 3 can also play a role in protecting the first conducting layer 2 from corrosion or damage caused by factors such as water vapor in the external environment during the use of the first conducting layer 2.

Exemplarily, the material of the first protecting layer 3 can be an inorganic insulating material.

For example, the inorganic insulating material may be one or a combination of more of silicon nitride, silicon oxide and silicon oxynitride.

In the exemplary embodiment, as shown in FIG. 4, the organic layer 4 is a full-surface continuous structure, the organic layer 4 covers most of the area of the first protecting layer 3, and the supporting portion sets 5G are evenly distributed on the organic layer 4.

In the exemplary embodiment, as shown in FIG. 5 or FIG. 6, the organic layer 4 includes a plurality of discontinuous (or called interval setting) raised height portions 41, there is a slot C disposed between any two adjacent raised height portions 41, and the supporting portions 5 in the same supporting portion set 5G are disposed on the same raised height portion 41.

The direct contact between at least part of areas of each supporting portion 5 and the organic layer 4 includes but is not limited to the following cases:

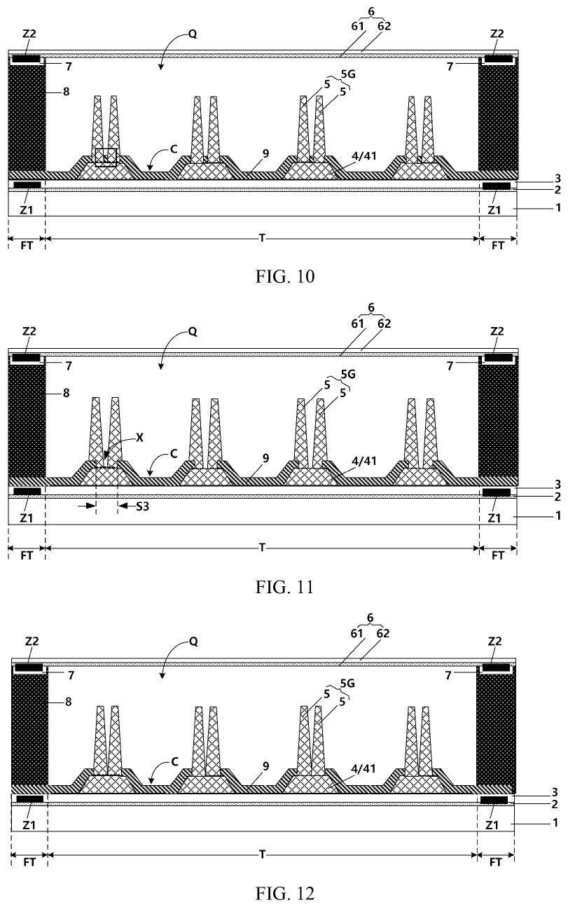

First, as shown in FIGS. 4 to 7. FIG. 9, FIG. 10 and FIG. 12, all the areas of the bottom of each supporting portion 5 are directly contacted with the organic layer 4.

Second, as shown in FIG. 8 and FIG. 11, a part of the areas of the bottom of each supporting portion 5 is directly contacted with the organic layer 4.

In practical applications, the larger the area of the area of the bottom surface of each supporting portion 5 directly contacted with the organic layer 4 is, the more favorable it is to improve the interfacial adhesion force between the supporting portion 5 and the organic layer 4, thereby the vibration stability of the supporting portion 5 in the vibration process of the sound-generating device is improved, the probability of the falling off of the supporting portion is reduced, the quality of the sound-generating device is improved and the effect of the directional sound-generating of the sound-generating device is ensured.

Here, there is no restriction on whether a type of the material of the above organic layer 4 and a type of the material of the supporting portion 5 are the same.

In the exemplary embodiment, the type of the material of the above organic layer 4 and the type of the material of the supporting portion 5 are the same. For example, both the material of the organic layer 4 and the material of the supporting portion 5 are an organic material, and the organic material may include organic polymeric material. There is a good adhesion between materials of the same type.

Here, the specific material of the above organic layer 4 is not limited, for example, the organic material may be a synthetic resin, rubber, a composite material of resin and fiber, a composite material of rubber and fiber, etc.

Exemplarily, both the material of the above organic layer 4 and the material of the supporting portion 5 may be synthetic resins. For example, both the material of the above organic layer 4 and the material of the supporting portion 5 may be one of polymethyl methacrylate (PMMA), polystyrene (PS), polycarbonate (PC), allyl diethylene glycol carbonate (CR-39), polyimide (PI), polyethylene terephthalate (PET) or epoxy optical plastics.

In the plurality of supporting portion sets 5G arranged in the array, the quantity of the supporting portions 5 included in each supporting portion set 5G is the same, the structure of each supporting portion set 5G is the same, and the size of each supporting portion set 5G is the same to ensure that supporting portion sets 56 are evenly arranged in the sound-generating device, so as to improve the effect of the directional sound-generating of the sound-generating device and the uniformity of sound wave propagation.

Here, there is no limit on the quantity of the supporting portions 5 included in each supporting portion set 5G.

Exemplarily, to simplify the design, each supporting portion set 5G can be configured to include only one supporting portion 5. In this way, the structures and sizes of all supporting portions 5 in the sound-generating device are the same.

The structure of the supporting portion 5 includes the shapes of the plane graph of the supporting portion 5 and the cross-sectional graph of the supporting portion 5. The size of the supporting portion 5 includes a height, a plane size and a cross-sectional size. The plane size is a size of a plane graph of the orthographic projection of the supporting portion 5 on the first substrate 1, and the cross-sectional size is a size of the cross-sectional graph of the supporting portion 5 in a direction perpendicular to the first substrate 1.

Exemplarily, in some embodiments, in order to improve the product reliability of the sound-generating device and reduce the risk of the falling off of the supporting portion 5 during the sound-generating vibration process, each supporting portion set 5G can be configured to include two or more supporting portions 5, in this way, the more supporting portions 5 there are, the smaller the amount of vibration energy each supporting portion 5 will be subjected to under the same vibration energy. This greatly reduces the risk of the failing off of the supporting portion 5.

When each supporting portion set 56 includes two or more supporting portions 5, there is no restriction on whether the structures and sizes of the plurality (two or more) of supporting portions 5 in the same supporting portion set 5G are the same. Taking that each supporting portion set 5G includes two supporting portions 5 (a first supporting portion and a second supporting portion) as an example, it can include but not be limited to the following situations:

First, the structure of the first supporting portion and the structure of the second supporting portion are the same, and the size of the first supporting portion and the size of the second supporting portion are the same.

Second, the structure of the first supporting portion and the structure of the second supporting portion are the same, but the size of the first supporting portion and the size of the second supporting portion are not exactly the same, that is, one or two of the height, the plane size and the cross-sectional size are different.

For example, the height of the first supporting portion is different from the height of the second supporting portion.

For example, the plane size of the first supporting portion and the plane size of the second supporting portion are different.

For example, the cross-sectional size of the first supporting portion and the cross-sectional size of the second supporting portion are different.

Third, the structure of the first supporting portion and the structure of the second supporting portion are different.

For example, the shape of the plane graph of the first supporting portion and the shape of the plane graph of the second supporting portion are different. Specifically, the shape of the plane graph of the first supporting portion can be an arc shape, and the shape of the plane graph of the first supporting portion can be a combination of are shapes and polygons.

The arc shape may include a circular shape, an elliptical shape, a semi-circular shape, a semi-elliptical shape, fan shape, etc. The Polygon may include a triangle, a quadrilateral, a pentagon, a hexagon, etc.

In some embodiments, the first conducting layer 2 can be called an ultrasonic wave electrode, which is configured to generate ultrasonic wave signals under the control of electrical signals. Each supporting portion 5 can play a role in regulating the directional transmission of the ultrasonic waves. The sound-generating vibration layer 6 vibrates after receiving the ultrasonic wave signals.

In the exemplary embodiments, the supporting portion set 5G is located in the cavity structure Q formed by the first protecting layer 3 and the sound-generating vibration layer 6, and there is a gap between the supporting portions in the supporting portion sets 5G and the sound-generating vibration layer 6. That is, the supporting portions 5 are not contacted with the sound-generating vibration layer 6.

In the direction perpendicular to the plane where the first substrate 1 is located, the depth of the cavity structure Q is greater than the height of the supporting portion 5.

In the embodiments of the present application, as shown in FIG. 4 to FIG. 12, by that the organic layer 4 is disposed between the first protecting layer 3 and the plurality of supporting portion sets 5G, and the area of the orthographic projection of the organic layer 4 on the first substrate 1 is greater than the sum of areas of the orthographic projections of all supporting portions 5 on the first substrate 1, and at least part of areas of each supporting pardon 5 is directly contacted with the organic layer 4, in this way, by using the organic layer 4, the force between the supporting portion sets 5G and the first protecting layer 3 can be increased. In the process of the vibration of the sound-generating device, the risk of the falling off of the supporting portion is greatly reduced. Thus, the quality of the sound-generating device is improved, and the effect of the directional sound-generating of the sound-generating device is ensured.

In the at least one embodiment of the present application, as shown in FIG. 4, the sound-generating device includes a light-transmitting area T and a non-light-transmitting area FT surrounding the light-transmitting area T. The orthographic projection of the organic layer 4 on the first substrate 1 covers the pan of the first substrate 1 located in the light-transmitting area T. and the supporting portion 5 is disposed on the organic layer 4.

In some examples, the type of the material of the supporting portion 5 and the type of the material of the organic layer 4 are the same.

In the embodiments of the present application, the supporting portions 5 are disposed on the organic layer 4 by disposing the full-surface and continuous organic layer 4 in the light-transmitting area T of the sound-generating device. The organic layer 4 (which is of organic material) can play a role in buffering the energy of the vibration. In addition, since the type of the material of the supporting portions 5 and the type of the material of the organic layer 4 are the same, the adhesion between the supporting portions 5 and organic layer 4 can be greatly improved, and the risk of the falling off of the supporting portion 5 is greatly reduced in the process of the vibration of the sound-generating device. Thus, the quality of the sound-generating device is improved, and the effect of the directional sound-generating of the sound-generating device is ensured.

In the at least one embodiment of the present application, as shown in FIG. 5 or FIG. 6, the organic layer 4 includes a plurality of raised height portions 41 arranged in an array, and there is a slot C between two adjacent raised height portions 41, and a quantity of the plurality of raised height portions 41 is the same as a quantity of the plurality of supporting portion sets 5G;

wherein, taking the structure shown in FIG. 5 as an example, an orthographic projection S1 of the supporting portion set 5G on the first substrate 1 is located within an orthographic projection S2 of a corresponding raised height portion 41 on the first substrate, and the at least part of areas of the supporting portion 5 in the supporting portion set 5G is directly contacted with the corresponding raised height portion 41.

In the exemplary embodiment, the size of the plane graph of the raised height portion 41 is greater than the size of the plane graph of the supporting portion set 5G. In this way, in the process of the vibration of the sound-generating device, because the organic layer 4 is of an organic material, the raised height portion 41 of the organic layer 4 can play a role in buffering the energy of the vibration, and the greater the size difference between the plane graph of the raised height portion 41 and the plane graph of the supporting portion set 5G is, the better the effect of buffering the energy of the vibration. Of course, the greater the size difference between the plane graph of the raised height portion 41 and the plane graph of the supporting portion set 5G, the greater the energy consumption, and the greater the power consumption of the sound-generating device. In practical applications, it is necessary to strike a balance between the two according to the performance requirements of the product.

Here, whether the type of the material of the supporting portion 5 and the type of the material of the raised height portion 41 are the same is not limited. In some examples, the type of the material of the supporting portion 5 and the type of the material of the raised height portion 41 may be set to be different. Of course, in practical applications, in order to improve the adhesion between the supporting portion 5 and the raised height portion 41, and further reduce the risk of the falling off of the supporting portion 5, the type of the material of the supporting portion 5 and the type of the material of the raised height portion 41 may be set to be the same. Itis even possible to set that the supporting portion 5 and the raised height portion 41 are manufactured by using the same material.

That the at least pan of areas of the supporting portion 5 in the supporting portion set 5G is directly contacted with the corresponding raised height portion 41 includes but is not limited to the following situations:

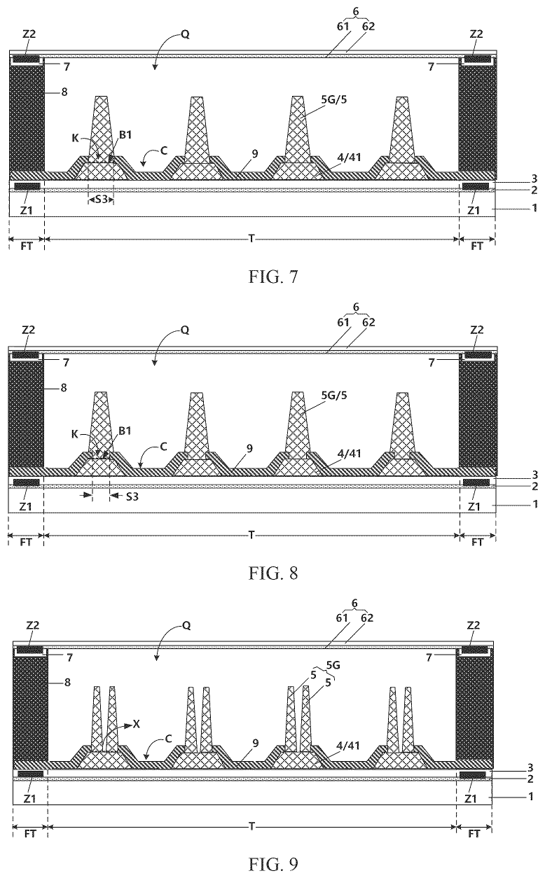

For example, as shown in FIG. 5, FIG. 6, FIG. 7, FIG. 9, FIG. 10 and FIG. 12, the entire areas of the bottom of the supporting portion 5 in the supporting portion set 5G are directly contacted with the corresponding raised height portion 41.

For another example, as shown in FIG. 8 and FIG. 11, the part of areas of the bottom of the supporting portion 5 in the supporting portion set 5G is directly contacted with the corresponding raised height portion 41.

In the embodiments of the present application, the supporting portion 5 is disposed on the corresponding raised height portion 41 by disposing that the organic layer 4 includes a plurality of raised height portions 41 arranged in the array. In the process of the vibration of the sound-generating device, the raised height portion 41 can play a role in buffering the energy of the vibration. It greatly reduces the risk of the falling off of the supporting portion 5, thus the quality of the sound-generating device is improved, and the effect of the directional sound-generating of the sound-generating device is ensured.

In the at least one embodiment of the present application, as shown in FIGS. 3 to 12, sizes of graphs of the orthographic projections of the plurality of raised height portions 41 on the first substrate 1 are the same; an area of the orthographic projection of each raised height portion 41 on the first substrate 1 is greater than at least 50% of the area of the orthographic projection of a corresponding supporting portion set 5G on the first substrate 1.

Exemplarily, the area of the orthographic projection of each raised height portion 41 on the first substrate 1 is greater than 50%, 55%, 60%, 65% or 68% of the area of the orthographic projection of the corresponding supporting portion set 5G on the first substrate 1.

In the embodiments of the present application, by disposing that the area of the orthographic projection of the raised height portion 41 on the first substrate 1 is greater than at least 50% of the area of the orthographic projection of the corresponding supporting portion set 5G on the first substrate 1, in the process of the vibration of the sound-generating device, the raised height portion 41 can play a good role in buffering the energy of the vibration. It greatly reduces the risk of the falling off of the supporting portion 5, thus the quality of the sound-generating device is improved, and the effect of the directional sound-generating of the sound-generating device is ensured.

In the at least one embodiment of the present application, as shown in FIGS. 5 to 12, each supporting portion 5 includes a first surface (e.g., the surface marked by B1 in FIG. 5, i.e., the bottom surface of the supporting portion 5), and at least part of areas of the first surface 31 is directly contacted with the corresponding raised height portion 41, and an area of a contacting surface between the supporting portion 5 and the raised height portion 41 is greater than at least 50% of an area of the first surface B1.

That is to say, for each supporting portion 5, more than 50% of the areas of the first surface B1 is directly contacted with the raised height portion 41, so as to ensure a good adhesion between the raised height portion 41 and the supporting portion 5. Thus, there is a good force between the supporting portion 5 and the first protecting layer 3 through the raised height portion 41, the falling off of the supporting portion 5 during the vibration of the sound-generating device is avoided, so that the quality of the sound-generating device is improved, and the effect of the directional sound-generating of the sound-generating device is ensured.

In the at least one embodiment of the present application, as shown in FIG. 6, FIG. 9 to FIG. 12, each supporting portion set 5G includes at least two supporting portions 5. The orthographic projections of the at least two supporting portions 5 in a same supporting portion set 5G on the first substrate 1 are located within the orthographic projection of the corresponding raised height portion 41 on the first substrate 1.

As shown in FIG. 6, FIG. 9, FIG. 10 and FIG. 11, there is a gap X between two adjacent supporting portions 5 in the same supporting portion set 5G, or, as shown in FIG. 12, the two adjacent supporting portions 5 in the same supporting portion set 5G are connected.

Here, the size of the above gap is not limited, which can be determined according to the design space and process accuracy of the actual product.

It should be noted that in some embodiments, a gap X may be disposed between the two adjacent supporting portions 5 in each supporting portion set 5G in the same sound-generating device. In some other embodiments, the two adjacent supporting portions 5 in each supporting portion set 5G in the same sound-generating device can be disposed to be connected. In some other embodiments, a gap X may be disposed between two adjacent supporting portions 3 in each supporting portion set 5G in a part of areas of the sound-generating device, and the two adjacent supporting portions 5 in each supporting portion set 5G in another part of the sound-generating device can be disposed to be connected.

In the at least one embodiment of the present application, as shown in FIGS. 7 to 12, the sound-generating device further includes an inorganic layer 9, the inorganic layer 9 is located at one side of the organic layer 4 away from the first substrate 1, the inorganic layer 9 at least covers side surfaces of the plurality of raised height portions 41 and extends to cover a bottom of the slot C, and a part of the inorganic layer 9 located at the bottom of the slot C is directly contacted with the first protecting layer 3.

In some embodiments, the material of the inorganic layer 9 and the material of the first protecting layer 3 are both inorganic materials.

Exemplarily, the material of the inorganic layer 9 can be one or a combination of more of silicon nitride, silicon oxide, or silicon oxynitride.

Exemplarily, the material of the inorganic layer 9 and the material of the first protecting layer 3 can be the same.

In exemplary embodiments, as shown in FIGS. 7 to 12, the inorganic layer 9 can also be extended from the side surface of the raised height portion 41 to a surface of a side of the raised height portion 41 away from the first substrate 1, the area of the contacting surface between the inorganic layer 9 and the raised height portion 41 is increased, thus the adhesion force between the inorganic layer 9 and the raised height portion 41 are increased, and the probability of falling off between the inorganic layer 9 and the raised height portion 41 during the vibration of the sound-generating device is reduced.

In the embodiment of the present application, by disposing the inorganic layer 9 in the sound-generating device, and the inorganic layer 9 at least covers the side surfaces of the raised height portions 41 and extends to cover the bosom of the slot C, the pan of the inorganic layer 9 located at the bottom of the slot C is directly contacted with the first protecting layer 3. In this way, the inorganic layer 9 can improve the adhesion between the raised height portion 41 and the first protecting layer 3, and avoid the overall falling off of the supporting portions 5 and the raised height portions 41 during the vibration of the sound-generating device, thus the quality of the sound-generating device is improved, and the effect of the directional sound-generating of the sound-generating device is ensured.

In the at least one embodiment of the present application, as shown in FIGS. 7 to 12, there are a plurality of openings K (marked by K in FIG. 8) on the inorganic layer 9, and an area enclosed by an orthographic projection of an outer contour of each opening K on the first substrate 1 is located within an orthographic projection of the corresponding raised height portion 41 on the first substrate 1, and the at least part of areas of the supporting portion 5 is located within the opening K.

In the exemplary embodiments, as shown in FIGS. 7, 9 and 10, the bottom (i.e., the bottom surface, or referred to as the first surface B1) of the supporting portion 5 is located in the opening K.

In the exemplary embodiment, as shown in FIG. 8 and FIG. 11, a part of the areas of the bottom (i.e., the bottom surface, or first surface B1) of the supporting portion 5 is located in the opening K, and a part of the areas of the bottom of the supporting portion 5 is disposed at one side of the inorganic layer 9 away from the first substrate 1 (i.e., disposed on the inorganic layer 9).

In the exemplary embodiment, when the same raised height portion 41 is provided with two or more supporting portions 5, there is no limit on the quantity of the openings K disposed on the part of the organic layer 9 located on the same raised height portion 41.

In some embodiments, as shown in FIG. 9. FIG. 11, or FIG. 12, an opening K may be disposed on a raised height portion 41 to place at least part of areas of the supporting portions 5 in the same supporting portion set 5G in the same opening K.

In some other embodiments, as shown in FIG. 10, two or more openings K can be disposed on a raised height portion 41, and at least part of areas of a supporting portion 5 can be disposed in an opening K. At this moment, as shown in the area marked by the rectangular box in FIG. 10, the area located between the two adjacent supporting portions 5 on the same raised height portion 41 is provided with the organic layer 4.

In practical applications, an opening K can be disposed on a raised height portion 41 to dispose at least part of areas of the supporting portions 5 in the same supporting portion set 5G in the same opening K, thus the design can be simplified, and the difficulty of the preparation process is reduced.

In the at least one embodiment of the present application, as shown in FIG. 7 or FIG. 9, a size of an area enclosed by an outer contour of a same supporting portion set 5G is less than or equal to a size of an area enclosed by the outer contour of the opening K, and the corresponding supporting portion 5 is disposed within the corresponding opening K and is directly contacted with the corresponding raised height portion 41.

In the exemplary embodiment, as shown in FIG. 7 or FIG. 9, the size (e.g. the area S3) of the plane graph of the area enclosed by the outer contour of the same supporting portion set 5G is approximately the same as the size (e.g. area) of the plane graph of the area enclosed by the outer contour of the opening K. At this moment, a part of areas of the side surface of the supporting portion 5 in the same supporting portion set 5G can be directly contacted with the inorganic layer 9.

In the exemplary embodiment, the sin (e.g. area) of the plane graph of the area enclosed by the outer contour of the same supporting portion set 5G is less than the size (e.g. area) of the plane graph of the area enclosed by the outer contour of the opening K. At this moment, there is a gap between a part of areas of the side surface of the supporting portion 5 in the same supporting portion set 5G and the inorganic layer 9.

It should be noted that the area enclosed by the outer contour of the same supporting portion set 5G includes the area of the areas where all supporting portions 5 in the same supporting portion set 5G are located, and also includes the area occupied by the gap between the supporting portions 5 in the same supporting portion set 5G.

In the at least one embodiment of the present application, as shown in FIG. 8 or FIG. 11, a size of an area enclosed by an outer contour of a same supporting portion set 5G is greater than a size of an area enclosed by the outer contour of the opening K, a part of areas of the corresponding supporting portion 5 is disposed within the corresponding opening K, and the corresponding supporting portion 5 further covers a part of the inorganic layer 9.

In the exemplary embodiment, as shown in FIG. 8 or FIG. 11, the area of the plane graph of the area enclosed by the outer contour of the same supporting portion set 5G is less than the area of the plane graph of the area enclosed by the outer contour of the opening K, so that a part of the areas of the supporting portion 5 is disposed on the inorganic layer 9.

It should be noted that for the case shown in FIG. 8 or FIG. 11, the area of the area where the supporting portions 5 in the same supporting portion set 5G are directly contacted with the raised height portion 41 is greater than the area of the area where the supporting portions 5 in the same supporting portion set 5G are directly contacted with the inorganic layer 9.

In some embodiments, a structure of the left part of the same supporting portion set 5G is completely disposed in the opening, and a structure of the right part of the same supporting portion set 5G has a local area disposed on the inorganic layer 9. Of course, it can also be that the structure of the right part of the same supporting portion set 5G is completely disposed in the opening, and the structure of the left pan of the same supporting portion set 5G has a local area disposed on the inorganic layer 9.

In the at least one embodiment of the present application, a material of the supporting portion 5 is the same as a material of the organic layer 4.

In the embodiments of the present application, when the material of the supporting portion 5 is the same as the material of the organic layer 4, the interfacial adhesion between the supporting portion 5 and the organic layer 4 can be greatly improved, so as to avoid the falling off of the supporting portion 5 during the vibration of the sound-generating device. Thus, the quality of the sound-generating device is improved, and the effect of the directional sound-generating of the sound-generating device is ensured.

In the at least one embodiment of the present application, a material of the inorganic layer 9 is the same as a material of the first protecting layer 3. When a part of the inorganic layer 9 located at the bottom of the slot C is directly contacted with the first protecting layer 3, since the material of the inorganic layer 9 is the same as the material of the first protecting layer 3, the interfacial adhesion between the inorganic layer 9 and the first protecting layer 3 is larger. In this way, the inorganic layer 9 can improve the adhesion between the raised height portion 41 and the first protecting layer 3, and avoid the overall falling off of the supporting portion 5 and the raised height portion 41 during the vibration of the sound-generating device, thus the quality of the sound-generating device is improved, and the effect of the directional sound-generating of the sound-generating device is ensured.

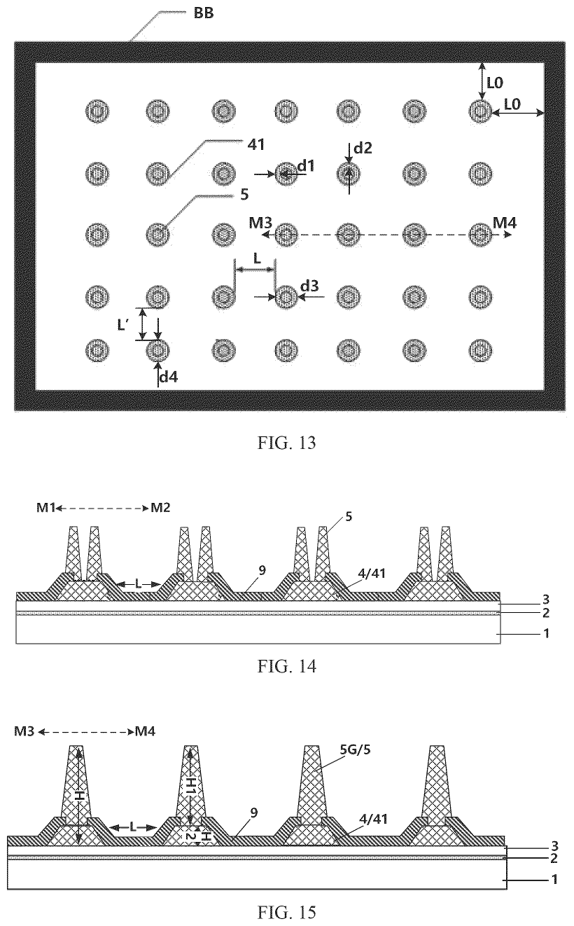

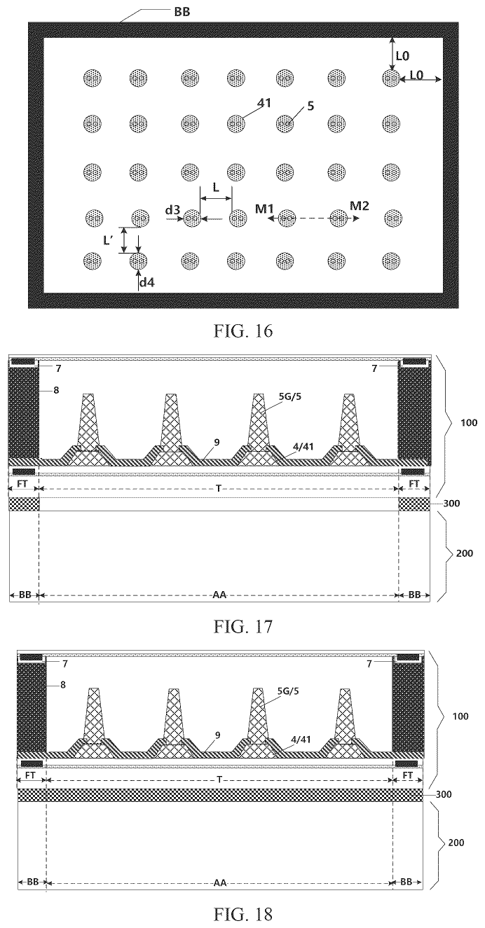

In the at least one embodiment of the present application, as shown in FIG. 13 and FIG. 16, a geometric center of a graph of the orthographic projection of the supporting portion set 5G on the first substrate 1 approximately overlaps with a geometric center of a graph of the orthographic projection of the corresponding raised height portion 5 on the first substrate 1.

Exemplarily, taking the structural diagram shown in FIG. 13 as an example, when the supporting portion set 5G includes two supporting portions 5. The geometric center of the graph of the orthographic projection of the supporting portion set 5G on the first substrate 1 is located in the area between the graphs of the orthographic projections of two supporting portions 5 on the first substrate 1. The geometric center of the graph of the of orthographic projection of the raised height portion 5 on the first substrate 1 and the geometric center of the graph of the orthographic projection of the supporting portion set 5G on first substrate 1 approximately overlap.

Exemplarily, taking the structural diagram shown in FIG. 16 as an example, when the supporting portion set 5G includes one supporting portion 5, the geometric center of the graph of the orthographic projection of the supporting portion 5 on the first substrate 1 approximately overlaps with the geometric center of the graph of the orthographic projection of the raised height portion 41 on the first substrate 1.

In the embodiment of the present application, by disposing that the geometric center of the graph of the orthographic projection of the supporting portion set 5G on the first substrate 1 and the geometric center of the graph of the orthographic projection of the raised height portion 5 on the first substrate 1 approximately overlap, the supporting portion set 5G is distributed as close as possible to the center of the raised height portion 5. In this way, during the process of the vibration of the sound-generating device, the energy generated by the vibration can be evenly transmitted to the raised height portions 5 and each supporting portion 5 in the supporting portion set 5G, so that each supporting portion 5 receives the same vibration energy as much as possible. Thereby the problem of the failing off of the supporting portion 5 caused by excessive vibration energy in the same supporting portion set 5G is reduced, thus the quality of the sound-generating device is improved, and the effect of the directional sound-generating of the sound-generating device and the uniformity of sound wave propagation are improved.

In the at least one embodiment of the present application, when the supporting portion set 5G includes a supporting portion 5, in any direction parallel to a plane where the first substrate 1 is located, distances from edges of a graph of an orthographic projection of the supporting portion 5 on the first substrate 1 to edges of a graph of the orthographic projection of the corresponding raised height portion 41 on the first substrate 1 are approximately equal.

In some embodiments, as shown in FIG. 16, the shape of the graph of the orthographic projection of the supporting portion 5 on the first substrate 1 is the same as the shape of the graph of the orthographic projection of the raised height portion 41 on the first substrate 1, and the geometric centers of the two approximately overlap. In this way, in any direction parallel to the plane where the first substrate 1 is located, distances from the edges of the graph of the orthographic projection of the supporting portion 5 on the first substrate 1 to the edges of the graph of the orthographic projection of the corresponding raised height portion 41 on the first substrate 1 are approximately equal.

Exemplarily, as shown in FIG. 13, the shape of the graph of the orthographic projection of the supporting portion 5 on the first substrate 1 is the same as the shape of the graph of the orthographic projection of the raised height portion 41 on the first substrate 1, and both of them are a circular shape or an elliptical shape. The geometric centers of the two approximately overlap. In the first direction parallel to the plane where the first substrate 1 is located, the distance from the edge of the graph of the orthographic projection of the supporting portion 5 on the first substrate 1 to the edge of the graph of the orthographic projection of the raised height portion 41 on the first substrate 1 is d1. In the second direction parallel to the plane where the first substrate 1 is located, the distance from the edge of the graph of the orthographic projection of the supporting portion 5 on the first substrate 1 to the edge of the graph of the orthographic projection of the raised height portion 41 on the first substrate 1 is d2, and d is approximately equal to d2. The first direction can be a vertical direction, and the second direction can be a horizontal direction.

In the embodiment of the present application, when the supporting portion set 5G includes a supporting portion 5, by disposing that in any direction parallel to the plane where the first substrate 1 is located, distances from the edges of the graph of the orthographic projection of the supporting portion 5 on the first substrate 1 to the edges of the graph of the orthographic projection of the corresponding raised height portion 41 on the first substrate 1 are approximately equal, in this way, the supporting portion 5 can be distributed in the middle position of the raised height portion 41. During the process of the vibration of the sound-generating device, the energy generated by the vibration can be uniformly transmitted to the raised height portion 5 and the supporting portion 5, so that the vibration energy received by the supporting portion 5 from different directions is as consistent as possible. Thereby the peeling problem caused by the excessive vibration energy subjected by the local area in the supporting portion 5 is reduced, thus the quality of the sound-generating device is improved, the effect of the directional sound-generating of the sound-generating device and the uniformity of sound wave propagation are improved.

In the at least one embodiment of the present application, in any direction parallel to a plane where the first substrate 1 is located, a size of the slot C is greater than a size of the corresponding raised height portion 41.

In the exemplary embodiment, as shown in FIG. 13 or FIG. 16, in the first direction (e.g., the horizontal direction) parallel to the plane where the first substrate 1 is located, the size L of the slot C is greater than the size d3 of the raised height portion 41.

In the exemplary embodiment, as shown in FIG. 13 or FIG. 16, in the second direction (e.g., the vertical direction) parallel to the plane where the first substrate 1 is located, the size L′ of the slot C is greater than the size d4 of the raised height portion 41.

In some embodiments, in the first direction (e.g., the horizontal direction) parallel to the plane where the first substrate 1 is located, the size d3 of the raised height portion 41 is approximately equal to the size d4 of the raised height portion 41 in the second direction (e.g., the vertical direction) parallel to the plane where the first substrate 1 is located.

In some embodiments, in the first direction (e.g., the horizontal direction) parallel to the plane where the first substrate 1 is located, the size L of the slot C is approximately equal to the size L′ of the slot C in the second direction (e.g., the vertical direction) parallel to the plane where the first substrate 1 is located.

In the at least one embodiment of the present application, a distance between any two adjacent raised height portions 41 ranges from 0.5 mm to 5 mm.

Exemplarily, the distance between any two adjacent raised height portions 41 may be 0.8 mm, 1.0 mm, 1.3 mm, 1.5 mm, 1.8 mm, 2.0 mm, 2.3 mm, 2.5 mm, 2.8 mm, 3.0 mm, 3.3 mm, 3.5 mm, 3.8 mm, 4.0 mm, 4.3 mm, 4.5 mm, 4.8 mm or 5 mm.

In the exemplary embodiments, the distances between any two adjacent raised height portions 41 may be set to be approximately equal in the first direction (e.g., the horizontal direction) or the second direction (e.g., the vertical direction), since the supporting portion set 5G is disposed on the raised height portion 41, disposing that the distances between any two adjacent raised height portions 41 in the first direction (e.g., the horizontal direction) or the second direction (e.g., the vertical direction) are approximately equal is helpful for that the supporting portion sets 5G can be evenly distributed on the first substrate 1, so as to help the supporting portion sets 5G to play a role in the directional propagation of the ultrasonic wave signals, and adjusting the directional sound transmission. At the same time, the uniformity of the directional sound transmission is improved, thus the quality of the sound-generating device is improved, and the effect of the directional sound-generating of the sound-generating device is ensured.

In the at least one embodiment of the present application, as shown in FIGS. 4 to 12, heights of the supporting portions 5 in the same supporting portion set 5G in the direction perpendicular to the first substrate 1 are equal (approximately equal).

Exemplarily, as shown in FIG. 6 and FIG. 9 to 12, when the same supporting portion set 5G includes two supporting portions 5, the heights of the supporting portions 5 in the same supporting portion set 5G in the direction perpendicular to the first substrate 1 are equal (approximately equal).

In the at least one embodiment of the present application, the heights of the supporting portions 5 in the same supporting portion set 5G in the direction perpendicular to the first substrate 1 is at least partially different.

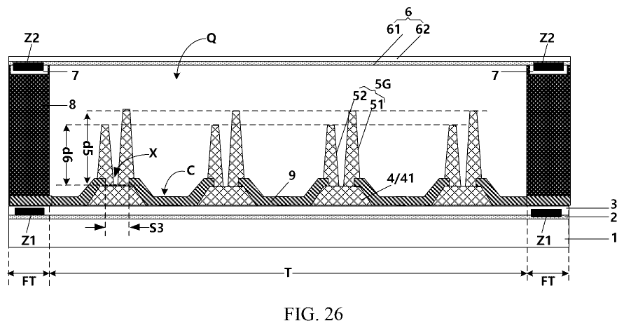

In the at least one embodiment of the present application, as shown in FIG. 26, each supporting portion set 5G includes a first supporting portion 51 and a second supporting portion 52, heights d5 of the first supporting portions 51 in a direction perpendicular to the first substrate 1 are equal, heights d6 of the second supporting portions 52 in the direction perpendicular to the first substrate 1 are equal, and the height d5 of the first supporting portion 51 in the direction perpendicular to the first substrate 1 is greater than the height d6 of the second supporting portion 52 in the direction perpendicular to the first substrate 1.

In the at least one embodiment of the present application, as shown in FIGS. 4 to 12, the sound-generating vibration layer 6 includes a second substrate 62 and a second conducting layer 61 located between the second substrate 62 and the supporting portion set 5G, the cavity structure Q is formed between the first protecting layer 3 and the second conducting layer 61, and the supporting portion set 5G is located in the cavity structure Q.

Taking the marker shown in FIG. 4 as an example, a height H3 of each supporting portion 5 in a direction perpendicular to the plane where the first substrate 1 is located is less than a minimum distance H4 from a surface of the supporting portion 5 adjacent to the first substrate 1 to the second conducting layer 61.

In the exemplary embodiment, a material of the second substrate 62 is a flexible material to vibrate during the process of the sound-generating of the sound-generating device.

In some examples, the material of the second substrate 62 can be made from one or more of the materials of polyimide, polycarbonate, polyacrylate, polyetherimide, and polyethersulfone. The present embodiment includes, but is not limited to, this.

In some examples, the second substrate 62 may include a single layer of a flexible material layer to avoid reducing its vibration efficiency due to the large quantity or large thickness of the film layer.

Here, the material of the second conducting layer 61 is not limited.

In some examples, the material of the second conducting layer 61 is a transparent conductive material.

Exemplarily, the material of the second conducting layer 61 is a metal. At this moment, in order to achieve light transmittance, the metal film has a small thickness. For example, the thickness of the metal film is on the nanometer scale.

Exemplarily, the material of the second conducting layer 61 is a metal oxide, such as indium tin oxide (IO) or indium zinc oxide (IZO).

Here, the magnitude of the difference between the height H3 of each supporting portion 5 in the direction perpendicular to the plane where the first substrate 1 is located and the minimum distance H4 from the surface of the supporting portion 5 adjacent to the first substrate 1 to the second conducting layer 61 is not limited. Specifically, it can be designed based on the size of the sound-generating device, the material of the sound-generating vibration layer 6, the thickness of the sound-generating vibration layer 6, and the sound-generating power of the sound-generating device.

In the embodiments of the present application, the supporting portions 5 are not contacted with the sound-generating vibration layer 6 in a stationary state.

In some embodiments, in the sound-generating state of the sound-generating device, at least part of the supporting portions 5 are not contacted with the sound-generating vibration layer 6.

Compared with the related art, it is disposed that the height H3 of each supporting portion 5 in the direction perpendicular to the plane where the first substrate 1 is located is approximately equal to the minimum distance H4 from the surface of the supporting portion 5 adjacent to the first substrate 1 to the second conducting layer 61, in the embodiments of the present application, by disposing that the height H3 of each supporting portion 5 in the direction perpendicular to the plane where the first substrate 1 is located is less than the minimum distance H4 from the surface of the supporting portion 5 adjacent to the first substrate 1 to the second conducting layer 6, there is a certain space between each supporting portion 5 and the sound-generating vibration layer 6. In practical applications, the sound-generating vibration layer 6 can have a larger amplitude, and make the vibration of the sound-generating vibration layer 6 cause less damage to the supporting portion 5, which can prolong the service life of the sound-generating device. In addition, while facilitating the supporting portion set 5G to play a role in the directional propagation of ultrasonic wave signals and adjusting the directional sound transmission, the uniformity of the directional sound transmission is improved, thereby the quality of the sound-generating device is improved, and the effect of the directional sound-generating of the sound-generating device is ensured.

In the at least one embodiment of the present application, as shown in FIGS. 4 to 12 and FIG. 26, the sound-generating device includes a light-transmitting area T and a non-light-transmitting area FT surrounding the light-transmitting area T, the supporting portion sets 5G are disposed in the light-transmitting area T.

The non-light-transmitting area FT includes a first perimeter wiring Z1, a second perimeter wiring Z2, a second protecting layer 7 and a bonding portion 8, the first perimeter wiring Z1 is located between the first conducting layer 2 and the first protecting layer 3; the first perimeter wiring Z1 and the first conducting layer 2 are electrically connected; the second perimeter wiring Z2 is disposed at one side of the second conducting layer 61 close to the first substrate 1, and the second protecting layer 7 covers a side of the second perimeter wiring Z2 away from the second conducting layer 61; the second perimeter wiring Z2 and the second conducting layer 61 are electrically connected; at least part of areas of the bonding portion 8 is disposed between the inorganic layer 9 and the second protecting layer 7; wherein in the direction perpendicular to the plane where the first substrate 1 is located, a height of the bonding portion 7 is greater than a sum of a height of the supporting portion 5 and a height of the corresponding raised height portion 41.

In the exemplary embodiment, the first perimeter wiring Z1 and the second perimeter wiring Z2 are set around the light-transmitting area T.

The specific materials of the first perimeter wiring Z1 and the second perimeter wiring Z2 are not limited here.

Exemplarily, the materials of the first perimeter wiring Z1 and the second perimeter wiring Z2 include metals or metal oxides, for example, the metals may include one or a combination of more of gold (Au), silver (Ag), copper (Cu), aluminum (Al), molybdenum (Mo) and titanium (Ti). For example, the metal oxides may include indium tin oxide (ITO) or indium zinc oxide (IZO).

Here, whether the materials and line widths of the first perimeter wiring Z1 and the second perimeter wiring Z2 are the same or not is not limited, which can be specifically determined according to the product design.

In some embodiments, in order to simplify the design and reduce the difficulty of the preparation process, the material of the first perimeter wiring Z1 and the material of the second perimeter wiring Z2 can be designed to be the same.

In the exemplary embodiment, the material of the second protecting layer 7 is an inorganic material.

In the exemplary embodiment, the material of the second protecting layer 7 is an insulating material, which is used to isolate the second perimeter wiring Z2 from other conductive materials to avoid short circuit in the circuit. In addition, the second protecting layer 7 can also play a role in protecting the second perimeter wiring Z2 from corrosion or damage caused by it factors such as water vapor in the external environment during the use of the second perimeter wiring Z2.

Exemplarily, the material of the second protecting layer 7 can be an inorganic insulating material.

For example, the inorganic insulating material may be one or a combination of more of silicon nitride, silicon oxide, and silicon oxynitride.

In the exemplary embodiments, the material of the bonding portion 8 above may include any one of glue, adhesive materials, tape, bonding agents, or frame adhesives (Seal).

The above bonding portion 8 is disposed in the non-light-transmitting area FT. The shape of the graph of the orthographic projection of the bonding portion 8 on the first substrate 1 is a ring, wherein the width of the ring is less than or equal to the width of the non-light-transmitting area FT.

At least part of areas of the bonding portion g is disposed between the inorganic layer 9 and the second protecting layer 7, including but not limited to the following situations:

First, as shown in FIG. 4 to FIG. 12 and FIG. 26, a part of areas of the bonding portion 8 is disposed between the inorganic layer 9 and the second protecting layer 7, and a part of areas of the bonding portion 8 is disposed between the second conducting layer 62 and the inorganic layer 9.

Second, all areas of the bonding portion 8 are disposed between the inorganic layer 9 and the second protecting layer 7, that is, the bonding portion 8 is completely disposed between the inorganic layer 9 and the second protecting layer 7.

In addition, in some embodiments, it can be set that in the direction perpendicular to the plane where the first substrate 1 is located, the height of the bonding portion 7 is greater than the sum of the heights of each supporting portion 5 and the raised height portion 41. In this way, the bonding layer 7 can support the sound-generating vibration layer 6 to be disposed away from the supporting portion 5, so that in a stationary state, each supporting portion 5 is not contacted with the sound-generating vibration layer 6.

Compared with the related art, it is disposed that in the stationary state, the supporting portions 5 are contacted with the sound-generating vibration layer 6, in the embodiments of the present application, by disposing that in the direction perpendicular to the plane where the first substrate 1 is located, the height of the bonding portion 7 is greater than the sum of the heights of each supporting portion 5 and the raised height portion 41, there is a certain space between each supporting portion 5 and the sound-generating vibration layer 6. In practical applications, the sound-generating vibration layer 6 can have a larger amplitude, and make the vibration of the sound-generating vibration layer 6 cause less damage to the supporting portion 5, which can prolong the service life of the sound-generating device. In addition, while facilitating the supporting portion sets 5G to play a role in the directional propagation of ultrasonic wave signals and adjusting the directional sound transmission, the uniformity of the directional sound transmission is improved, thereby the quality of the sound-generating device is improved, and the effect of the directional sound-generating of the sound-generating device is ensured.

In the at least one embodiment of the present application, as shown in FIG. 13 or FIG. 16, in a first direction (e.g., the horizontal direction) or a second direction (e.g., the vertical direction), distances L between any two adjacent raised height portions 41 are approximately equal.

In the first direction (e.g., the horizontal direction) or the second direction (e.g., the vertical direction), for the raised height portion 41 with a minimum distance to a junction position of the non-light-transmitting area FT and the light-transmitting area T, the distance L0 from the raised height portion 41 to the junction position is approximately equal to the distances L between any other two adjacent raised height portions 41, and the first direction (e.g., the horizontal direction) and the second direction (e.g., the vertical direction) are perpendicular.

In the embodiment of the present application, by disposing that in the first direction (e.g., the horizontal direction) or the second direction (e.g., the vertical direction), for the raised height portion 41 with the minimum distance to the junction position of the non-light-transmitting area FT and the light-transmitting area T, the distance L0 from the raised height portion 41 to the junction position is approximately equal to the distances L between any other two adjacent raised height portions 41, the raised height portions 41 in the sound-generating device close to die non-light-transmitting area FT can be evenly arranged. Since the supporting portion set 5G is disposed on the raised height portion 41, for the raised height portion 41 with the minimum distance to the junction position of the non-light-transmitting area FT and the light-transmitting area T, the distance L0 from the raised height portion 41 to the junction position is approximately equal to the distances L between any other two adjacent raised height portions 41, which helps the supporting portion sets 5G to be evenly distributed on the first substrate 1, while facilitating the supporting portion sets 5G to play a role in the directional propagation of ultrasonic wave signals and adjusting the directional sound transmission, the uniformity of the directional sound transmission is improved, thereby the quality of the sound-generating device is improved, and the effect of the directional sound-generating of the sound-generating device is ensured.

In the at least one embodiment of the present application, as shown in FIG. 14 or FIG. 15, the sum of the height of the supporting portion 5 and the height of the corresponding raised height portion 41 ranges from 4 μm to 15 μm.

FIG. 14 is a schematic diagram of a cross-sectional structure in FIG. 16 along an M1M2 direction, and FIG. 15 is a schematic diagram of a cross-sectional structure in FIG. 13 along an M3M4 direction. It should be noted that for the clarity and simplicity of the drawings, the sum of the height of the supporting portion 5 and the height of the corresponding raised height portion 41 is marked by H in FIG. 15.

In the exemplary embodiment, the sum H of the height of the supporting portion 5 and the height of the corresponding raised height portion 41 can be 4 μm, 5 μm, 5.5 μm, 6.0 μm, 6.5 μm, 7.0 μm, 7.5 μm, 8.2 μm, 8.5 μm, 9.0 μm, 9.5 μm, 10 μm, 10.5 μm, 11 μm, 11.5 μm, 12 μm, 12.5 μm, 13 μm, 13.5 μm, 14 μm or 14.5 μm.

It should be noted that for each raised height portion 41 where the projections overlap corresponding to the supporting portions 5 with a same position, the sums of the heights of the supporting portions 5 and the heights of the corresponding raised height portions 41 are equal.

In the at least one embodiment of the present application, as shown in FIG. 15, a ratio of the height of the supporting portion 3 to the height of the corresponding raised height portion 41 is approximately 5:3.

In practical applications, the supporting portion 5 mainly plays the role in the directional transmission of sound waves. The raised height portion 41 mainly plays the role in improving the adhesion of the supporting portion 5 and avoiding the falling off of the supporting portion 5. The thicker the raised height portion 41 is, the better the effect of improving the adhesion is, but it may have a negative impact on the effect of the directional transmission of the sound waves of the supporting portion 5. The thinner the raised height portion 41 is, the effect of improving the adhesion force is general, and the effect of the directional transmission of the sound waves of the supporting portion 5 is better. By disposing the ratio H1:H2 of the height of the supporting portion 5 to the height of the raised height portion 41 is approximately 5:3, the balance can be obtained between the two, so as to improve the adhesion force and the effect of the directional transmission of the sound waves. Thus, the quality of the sound-generating device is improved, and the effect of the directional sound-generating of the sound-generating device is ensured.

In the at least one embodiment of the present application as shown in FIG. 13 and FIG. 16, a shape of a graph of an orthographic projection of the supporting portion 5 on the first substrate 1 and a shape of a graph of the orthographic projection of the corresponding raised height portion 41 on the first substrate 1 are arc shapes.

Exemplarily, the arc shape may include a circular shape, an elliptical shape, a semi-circular shape, a semi-elliptical shape, a fan shape, a rounded polygon, etc.

In the embodiments of the present application, by disposing that a shape of a graph of an orthographic projection of the supporting portion 5 on the first substrate 1 and a shape of a graph of an orthographic projection of the corresponding raised height portion 41 on the first substrate 1 arm are shapes, in this way, in the process of the vibration of the sound-generating device, the vibration energy subjected by the supporting portion 5 and the raised height portion 41 in the directions tends to be consistent as much as possible. Thereby the problem of the falling off caused by the excessive vibration energy subjected by the local area of the supporting portion 5 is reduced, thus the quality of the sound-generating device is improved, the effect of the directional sound-generating of the sound-generating device and the uniformity of sound wave propagation are improved.

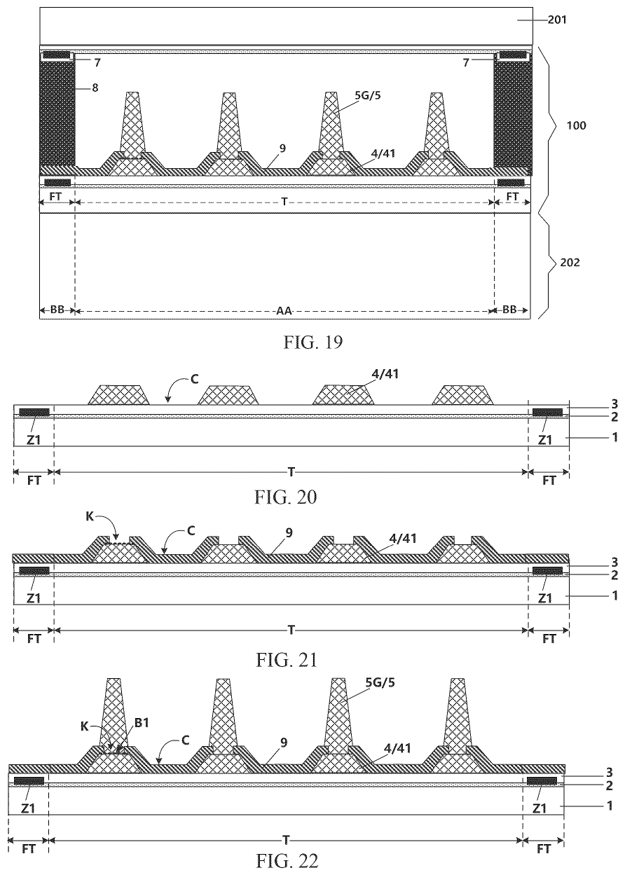

A display apparatus is provided by the embodiment of the present application, as shown in FIG. 17, FIG. 19 and FIG. 19, the display apparatus includes the sound-generating device 100 as described above, and also includes a display panel 20) (in FIG. 19, 200 includes 201 and 202); the sound-generating device 100 is disposed at a light exiting side of the display panel 200 or inside the display panel 200; and an orthographic projection of a light-transmitting area T of the sound-generating device 100 on the display panel 200 overlaps with a displaying region AA of the display panel 200.

The above display apparatuses can be an organic light-emitting diode (OLED) display apparatus, a Micro LED (Micro light-emitting diode) display apparatus, a Mini LED (Mini light-emitting diode) display apparatus or an LCD (liquid crystal display) display apparatus.

The display apparatus can include any device or product with a display function. For example, the display apparatuses may be smart phones, mobile phones e-book readers, desktop computers (PCs) laptop PCs, netbook PCs, personal digital assistants (PDAs), portable multimedia players (PMPs) digital audio players, mobile medical devices, cameras, wearable devices (such as head-mounted devices, electronic clothing, electronic bracelets, electronic necklaces, electronic accessories, electronic tattoos, or smart watches), televisions, etc.

In the exemplary embodiment, as shown in FIG. 17 and FIG. 18, the sound-generating device 100 is disposed at the light exiting side of the display pail 200.

Exemplarily, when the display panel 200 is one of the OLED display panel, the Micro LED display panel, the Mini LED display panel and the LCD display panel, the sound-generating device 100 can be disposed at the light exiting side of the display panel 200.

In the exemplary embodiment, as shown in FIG. 19, the sound-generating device 10 is disposed inside the display panel 200.

Exemplarily, when the display panel 200 is one of the OLED display panel, the Micro LED display panel and the Mini LED display panel, the sound-generating device 100 can be disposed inside the display panel 200.

No matter what type of the display panel is, the orthographic projection of the light-transmitting area T of the sound-generating device 100 on the display panel 200 overlaps with the displaying region AA of the display panel 200. The orthographic projection of the non-light-transmitting area FT of the sound-generating device 100 on the display panel 200 overlaps with the peripheral area 88 of the display panel 200.

In the display apparatus provided by the embodiments of the present application, by that the organic layer 4 is disposed between the first protecting layer 3 and the plurality of supporting portion sets 5G, and the area of the orthographic projection of the organic layer 4 on the nest substrate 1 is greater than the sum of areas of the orthographic projections of all supporting portions 5 on the first substrate 1, and at least part of areas of each supporting portion 5 is directly contacted with the organic layer 4, in this way, by using the organic layer 4, the force between the supporting portion sets 5G and the first protecting layer 3 can be increased. In the process of the vibration of the sound-generating device, the risk of the falling off of the supporting portion is greatly reduced. Thus, the quality of the sound-generating device is improved, and the effect of the directional sound-generating of the sound-generating device is ensured, so that a display apparatus with a surface sound-generating function can be manufactured.

In the at least one embodiment of the present application, the display panel 200 includes a liquid crystal display panel, the sound-generating device 100 is disposed at the light exiting side of the display panel 200; and
the orthographic projections of at least pan of the supporting portions 5 on the liquid crystal display panel overlap with spacers PS in the liquid crystal display panel.

In the exemplary embodiment, the orthographic projections of a part of the supporting portions 5 on the liquid crystal display panel overlap with the spacers PS in the liquid crystal display panel.

In the exemplary embodiment, the orthographic projection of each supporting portion 5 on the liquid crystal display panel overlaps with the corresponding spacer PS in the liquid crystal display pane.

The distribution density of the spacers PS in the liquid crystal display panel is greater than the distribution density of the supporting portions 5 in the sound-generating device 100.

In the display apparatus provided by the embodiment of the present application, since the sound-generating device 100 is disposed at the light exiting side of the display panel 200, by disposing the orthographic projections of at least part of the supporting portions 5 on the liquid crystal display panel overlap with the spacers PS in the liquid crystal display panel, the interference of the supporting portion 5 on the display light can be greatly reduced, so as to improve the light extraction efficiency of the display apparatus and improve the display effect.

In the at least one embodiment of the present application, the display panel 200 includes an organic light-emitting diode display panel (OLED). The sound-generating device 100 is disposed at the light exiting side of the display panel 200 or inside the display panel.

Exemplarily, when the sound-generating device 100 is disposed inside the display panel 200, since the OLED display panel 200 can include the light-emitting substrate 202 and the cover plate (or package substrate) 201, the sound-generating device 100 can be disposed between the light-emitting substrate 202 and the cover plate (or package substrate) 201.

In some embodiments, when the sound-generating device 100 is disposed between the light-emitting substrate 202 and the cover plate (or package substrate) 201, the first substrate 1 can be shared with the package layer or organic film layer in the light-emitting substrate 202, thereby the thickness of the display apparatus can be further reduced and the flexibility the application of the display apparatus is improved.

In the exemplary embodiment, as shown in FIG. 17, the ring-shaped connecting portion 300 can be disposed to fix the sound-generating device 100 and the display panel 200 together.

In the exemplary embodiment, as shown in FIG. 18, the sound-generating device 100 and the display panel 200 can be fixed together by disposing the full-surface connecting portion 300.

The material of the connecting portion 300 may include a frame adhesive.

A method for manufacturing the sound-generating device is provided by the embodiment of the present application, which is applied to the sound-generating device as stated above, the method includes:

S01, providing the first substrate 1 as shown in FIG. 20.

The material of the first substrate is not limited here.

In some examples, the first substrate may be a rigid substrate or a flexible substrate.

In some examples, the material of the first substrate 1 can be made from one or more of the materials of glass, polyimide, polycarbonate, polyacrylate, polyetherimide, and polyethersulfone, the present embodiment includes, but is not limited to this.

It should be noted that, when the sound-generating device is applied to the display apparatus, the first substrate can be preferred as a flexible substrate to reduce the thickness of the sound-generating device, thereby the volume of the display apparatus is reduced, the display apparatus is caused to be lighter and thinner, and the application scenario of the sound-generating device is expanded.

S02, as shown in FIG. 20, forming the first conducting layer 2, the first protecting layer 3 and the organic layer 4 on the first substrate 1, respectively;

In some examples, the material of the first conducting layer 2 is a transparent conductive material.

Exemplarily, the material of the first conducting layer 2 is metal. At this moment, in order to achieve light transmittance, the metal film layer has a small thickness. For example, a thickness of the metal film layer is on the nanometer scale.

Exemplarily, the material of the first conducting layer 2 is a metal oxide, such as indium tin oxide (ITO) or indium zinc oxide (IZO).

In the exemplary embodiment, the material of the first protecting layer 3 is an insulating material, which is used to isolate the first conducting layer 2 from other conductive materials to avoid short circuit in the circuit. In addition, the first protecting layer 3 can also play a role in protecting the first conducting layer 2 from corrosion or damage caused by factors such as water vapor in the external environment during the use of the first conducting layer 2.

Exemplarily, the material of the first protecting layer 3 can be an inorganic insulating material.

For example, the inorganic insulating material may be one or a combination of more of silicon nitride, silicon oxide and silicon oxynitride.

In the exemplary embodiment, as shown in FIG. 4, the organic layer 4 is a full-surface continuous structure, the organic layer 4 covers most of the area of the first protecting layer 3, and the supporting portion sets 5G are evenly distributed on the organic layer 4.

In the exemplary embodiment, as shown in FIG. 5 or FIG. 6, the organic layer 4 includes a plurality of discontinuous (or called interval setting) raised height portions 41, there is a slot C disposed between any two adjacent raised height portions 41, and the supporting portions 5 in the same supporting portion set 5G are disposed on the same raised height portion 41.

S03, as shown in FIG. 22, forming the plurality of supporting portion sets 5G arranged in the array; wherein each supporting portion set 5G includes at least one supporting portion 5, each of the at least one supporting portion 5 is located at the side of the organic layer 4 away from the first protecting layer 3, the area of the orthographic projection of the organic layer 4 on the first substrate 1 is greater than the sum of the areas of the orthographic projections of all supporting portions 5 on the first substrate 1, and at least part of areas of each supporting portion 5 is directly contacted with the organic layer 4.

In the exemplary embodiment, a type of the material of the first protecting layer 3 and a type of the material of the supporting portion 5 are different. For example, the material of the first protecting layer 3 is an inorganic material, and the material of the supporting portion 5 is an organic material.

In the exemplary embodiments, the material of the supporting portion 5 is a transparent material.

In practical applications, the larger the area of the area of the bottom surface of each supporting portion 5 directly contacted with the organic layer 4 is, the more favorable it is to improve the interfacial adhesion force between the supporting portion 5 and the organic layer 4, thereby the vibration stability of the supporting portion 5 in the vibration process of the sound-generating device is improved, the probability of the falling off of the supporting portion is reduced, the quality of the sound-generating device is improved and the effect of the directional sound-generating of the sound-generating device is ensured.

Here, there is no restriction on whether a type of the material of the above organic layer 4 and a type of the material of the supporting portion 5 are the same.

In the exemplary embodiment, the type of the material of the above organic layer 4 and the type of the material of the supporting portion 5 are the same. For example, both the material of the organic layer 4 and the material of the supporting portion 5 are an organic material, and the organic material may include organic polymeric material. There is a good adhesion between materials of the same type.

In the sound-generating device prepared by the manufacturing method provided in the embodiments of the present application, by that the organic layer 4 is disposed between the first protecting layer 3 and the plurality of supporting portion sets 5G, and the area of the orthographic projection of the organic layer 4 on the first substrate 1 is greater than the sum of areas of the orthographic projections of all supporting portions 5 on the first substrate 1, and at least part of areas of each supporting portion 5 is directly contacted with the organic layer 4, in this way, by using the organic layer 4, the force between the supporting portion sets 5G and the first protecting layer 3 can be increased. In the process of die vibration of the sound-generating device, the risk of the falling off of the supporting portion is greatly reduced. Thus, the quality of the sound-generating device is improved, and the effect of the directional sound-generating of the sound-generating device is ensured.

In the at least one embodiment of the present application, as shown in FIG. 5 or FIG. 6, the organic layer 4 includes a plurality of raised height portions 41 arranged in an array, and there is a slot C between the two adjacent raised height portions 41, and a quantity of the plurality of raised height portions 41 is the same as a quantity of the plurality of supporting portion sets 5G;
after the forming the organic layer in step S02, and before the forming the plurality of supporting portion sets arranged in the array in step S03 the method further includes:

S04, as shown in FIG. 21, forming a inorganic layer 9 on the organic layer 4; wherein there are a plurality of openings K on the inorganic layer 9, and an area enclosed by an orthographic projection of an outer contour of each opening K on the first substrate 1 is located within the orthographic projection of the corresponding raised height portion 41 on the first substrate 1, as shown in FIG. 22, the at least part of areas of the supporting portion 5 is directly contacted with the corresponding raised height portion 41 through a corresponding opening K.

In some embodiments, as shown in FIG. 9, FIG. 11, or FIG. 12, an opening K may be disposed on a raised height portion 41 to place at least pan of areas of the supporting portions 5 in the same supporting portion set 5G in the same opening K.

In some other embodiments, as shown in FIG. 10, two or more openings K can be disposed on a raised height portion 41, and at least part of areas of a supporting portion 5 can be disposed in an opening K. At this moment, as shown in the area marked by the rectangular box in FIG. 10, the area located between the two adjacent supporting portions 5 on the same raised height portion 41 is provided with the organic layer 4.

In practical applications, an opening K can be disposed on a raised height portion 41 to dispose at least part of areas of the supporting portions 5 in the sane supporting portion set 5G in the same opening K, thus the design can be simplified, and the difficulty of the preparation process is reduced.

In the at least one embodiment of the present application, after the forming the inorganic layer on the organic layer in step S04, and after the forming the plurality of supporting portion sets 5G, the method further includes:
S05, as shown in FIG. 24, providing a second substrate 62;
S06, as shown in FIG. 24, forming a second conducting layer 61 on the second substrate 62;
S07, disposing a bonding layer 8 in a part of the inorganic layer 9 located in the non-light-transmitting area FT of the sound-generating device 100, and the inorganic layer 9 and the second protecting layer 7 being bonded together by using the bonding layer 8.

In the exemplary embodiment, step S07 of disposing the bonding layer 8 in the part of the inorganic layer 9 located in the non-light-transmitting area FT of the sound-generating device 100, and the inorganic layer 9 and the second protecting layer 7 being bonded together by using the bonding layer 8 includes:
Sub-step 1: in a part of the inorganic layer 9 located in the non-light-transmitting area FT of the sound-generating device 100, performing glue coating by using a dispensing process;
Sub-step 2, aligning and bonding an intermediate structure (referred to as the first substrate) shown in FIG. 22 with an intermediate structure shown in FIG. 24 (referred to as the second substrate);
Sub-step 3, performing light curing treatment.

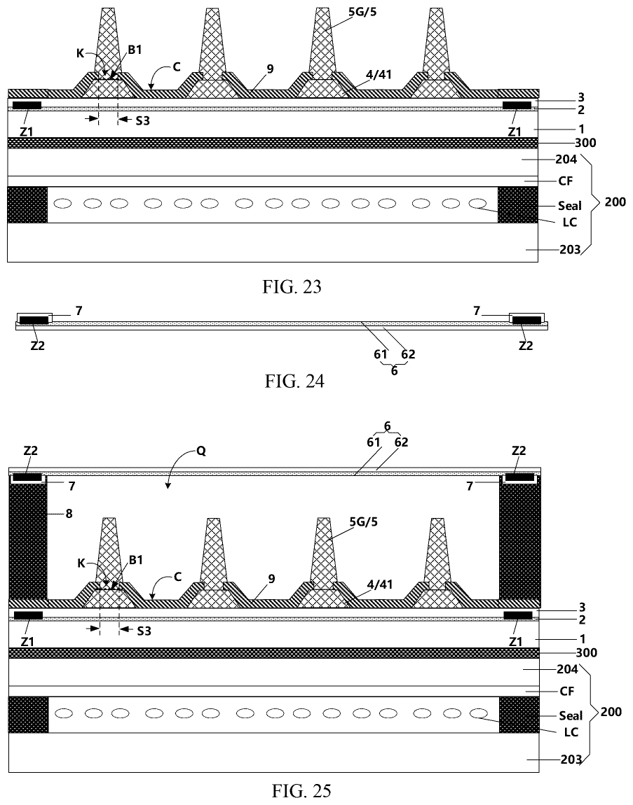

A method for manufacturing the display apparatus is further provided by the embodiment of the present application, wherein the method includes:
1, providing a display panel 200 as shown in FIG. 23;
2, as shown in FIG. 23, fixing the intermediate structure (referred to as the first substrate) shown in FIG. 22 on the display panel 200 through the connecting portion 300;
3, as shown in FIG. 24, fixing the intermediate structure (referred to as the second substrate) together by using the bonding layer 8 to obtain the display apparatus shown in FIG. 25.

It should be noted that both FIG. 23 and FIG. 25 are drawn by taking that the display panel 200 is the LCD display panel as an example, wherein the display panel 200 includes the array substrate 203, the liquid crystal layer (including the liquid crystal LC), the color film layer CF, the color film substrate 24 and the frame adhesive Seal. Of course, the display panel 200 can also include other structures and components. Specifically, the description in the related art can be referred to, which will not be repeated here.

It should be noted that only the manufacturing process of the structure related to the invention point is introduced here. The introduction of the specific components and materials of the sound-generating device and the display apparatus can be referred to the previous description, which will not be repeated here.

The above descriptions are only specific embodiments of the present application, however, the scope of protection of the present application is not limited thereto. A person skilled in the art can easily conceive of variations or substitutions within the technological scope revealed in the present application, which should be encompassed within the scope of protection of the present application. Therefore, the scope of protection of the present application should be determined by the scope of protection of the claims.

1. A sound-generating device, comprising:
a first substrate;
a first conducting layer located at one side of the first substrate;
a first protecting layer covering the first conducting layer;
an organic layer located at one side of the first protecting layer away from the first conducting layer;
a plurality of supporting portion sets arranged in an array, each of the plurality of supporting portion sets comprising at least one supporting portion, each of the at least one supporting portion being located at one side of the organic layer away from the first protecting layer;
a sound-generating vibration layer located at one side of each supporting portion set away from the first substrate, the plurality of supporting portion sets being located in a cavity structure formed by the first protecting layer and the sound-generating vibration layer;
wherein an area of an orthographic projection of the organic layer on the first substrate is greater than a sum of areas of orthographic projections of all supporting portions on the first substrate, and at least part of areas of each of the at least one supporting portion is directly contacted with the organic layer.

2. The sound-generating device according to claim 1, wherein the sound-generating device comprises a light-transmitting area and a non-light-transmitting area surrounding the light-transmitting area, the orthographic projection of the organic layer on the first substrate covers a part of the first substrate located in the light-transmitting area, each of the at least one supporting portion is disposed on the organic layer, and each of the at least one supporting portion and the organic layer are made of a same type of a material.

3. The sound-generating device according to claim 1, wherein the organic layer comprises a plurality of raised height portions arranged in an array, and there is a slot between two adjacent raised height portions, and a quantity of the plurality of raised height portions is the same as a quantity of the plurality of supporting portion sets;
wherein an orthographic projection of each supporting portion set on the first substrate is located within an orthographic projection of a corresponding raised height portion on the first substrate, and the at least part of areas of each of the at least one supporting portion in the supporting portion set is directly contacted with the corresponding raised height portion.

4. The sound-generating device according to claim 3, wherein sizes of graphs of the orthographic projections of the plurality of raised height portions on the first substrate are the same; an area of the orthographic projection of each raised height portion on the first substrate is greater than at least 50% of an area of an orthographic projection of a corresponding supporting portion set on the first substrate.

5. The sound-generating device according to claim 3, wherein each of the at least one supporting portion comprises a first surface, and at least part of areas of the first surface is directly contacted with the corresponding raised height portion, and an area of a contacting surface between the supporting portion and the corresponding raised height portion is greater than at least 50% of an area of the first surface.

6. The sound-generating device according to claim 3, wherein each supporting portion set comprises at least two supporting portions, orthographic projections of the at least two supporting portions in a same supporting portion set on the first substrate are located within the orthographic projection of the corresponding raised height portion on the first substrate, there is a gap between two adjacent supporting portions in the same supporting portion set, or the two adjacent supporting portions in the same supporting portion set are connected.

7. The sound-generating device according to claim 3, wherein the sound-generating device further comprises an inorganic layer, the inorganic layer is located at one side of the organic layer away from the first substrate, the inorganic layer at least covers side surfaces of the plurality of raised height portions and extends to cover a bottom of the slot, and a part of the inorganic layer located at the bottom of the slot is directly contacted with the first protecting layer.

8. The sound-generating device according to claim 7, wherein there are a plurality of openings on the inorganic layer, and an area enclosed by an orthographic projection of an outer contour of each opening on the first substrate is located within the orthographic projection of the corresponding raised height portion on the first substrate, and the at least part of areas of each of the at least one supporting portion is located within the opening.

9. The sound-generating device according to claim 8, wherein a size of an area enclosed by an outer contour of a same supporting portion set is less than or equal to a size of an area enclosed by an outer contour of a corresponding opening, and the corresponding supporting portion is disposed within the corresponding opening and is directly contacted with the corresponding raised height portion.

10. The sound-generating device according to claim 8, wherein a size of an area enclosed by an outer contour of a same supporting portion set is greater than a size of an area enclosed by an outer contour of a corresponding opening, a part of areas of the corresponding supporting portion is disposed within the corresponding opening, and the corresponding supporting portion further covers a part of the inorganic layer.

11. The sound-generating device according to claim 7, wherein a material of each of the at least one supporting portion is the same as a material of the organic layer.

12. The sound-generating device according to claim 11, wherein a material of the inorganic layer is the same as a material of the first protecting layer.

13. The sound-generating device according to claim 7, wherein a geometric center of a graph of the orthographic projection of each supporting portion set on the first substrate approximately overlaps with a geometric center of a graph of the orthographic projection of the corresponding raised height portion on the first substrate.

14. The sound-generating device according to claim 7, wherein when the supporting portion set comprises a supporting portion, in any direction parallel to a plane where the first substrate is located, distances from edges of a graph of an orthographic projection of the supporting portion on the first substrate to edges of a graph of the orthographic projection of the corresponding raised height portion on the first substrate are approximately equal.

15. The sound-generating device according to claim 7, wherein in any direction parallel to a plane where the first substrate is located, a size of the slot is greater than a size of each of the two adjacent raised height portions.

16. The sound-generating device according to claim 15, wherein a distance between any two adjacent raised height portions ranges from 0.5 mm to 5 mm.

17. The sound-generating device according to claim 7, wherein heights of the at least one supporting portion in a same supporting portion set in a direction perpendicular to the first substrate are equal.

18-24. (canceled)

25. A display apparatus, wherein the display apparatus comprises the sound-generating device according to claim 1, and further comprises a display panel, the sound-generating device is disposed at a light exiting side of the display panel or inside the display panel, and an orthographic projection of a light-transmitting area of the sound-generating device on the display panel overlaps with a displaying region of the display panel.

26. The display apparatus according to claim 25, wherein the display panel comprises a liquid crystal display panel, the sound-generating device is disposed at the light exiting side of the display panel; and
the orthographic projections of at least part of the at least one supporting portion on the liquid crystal display panel overlap with spacers in the liquid crystal display panel.

27. (canceled)

28. A method for manufacturing the sound-generating device, applied to the sound-generating device according to claim 7, wherein the method comprises:
providing the first substrate;
forming the first conducting layer, the first protecting layer and the organic layer on the first substrate, respectively; and
forming the plurality of supporting portion sets arranged in the array, wherein each of the plurality of supporting portion sets comprises at least one supporting portion, each of the at least one supporting portion is located at the side of the organic layer away from the first protecting layer; the area of the orthographic projection of the organic layer on the first substrate is greater than the sum of the areas of the orthographic projections of all supporting portions on the first substrate, and at least part of areas of each of the at least one supporting portion is directly contacted with the organic layer.

29-30. (canceled)
